(19) United States
(12) Patent Application Publication
(10) Pub. No.: US 2006/0208930 A1
(43) Pub. Date: Sep. 21, 2006

(54) Encoding method, decoding method, encoding system, recording method, reading method and recording system

(76) Inventor: Kohsuke Harada, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/375,009

(22) Filed: Mar. 15, 2006

(30) Foreign Application Priority Data
Mar. 16, 2005 (JP) 2005-075933

(51) Int. Cl. H03M 7/00

(52) U.S. Cl. 341/50

(57) ABSTRACT

Encoding-system includes a check-bit-generation-unit configured to generate N-ary-parity-bits by processing information composed of N-ary-symbols (where N is a power of 2) in modulo-N with a LDPC-matrix composed of binary elements, an encoded-sequence-generation-unit configured to generate an encoded sequence including the information composed of the N-ary-symbols and the N-ary-parity-bits, a modulation unit configured to modulate the encoded sequence in a modulation scheme having N-ary-modulation-symbols to produce a modulated signal, a demodulation-unit configured to demodulate the modulated signal to produce a demodulated signal, a metric-generation-unit configured to generate a metric for each of N-modulation-signal-points from the demodulated signal to obtain a plurality of metrics, and a decoding-unit configured to decode the encoded sequence by obtaining posteriori probabilities of the symbols in accordance with a state transition having an N-state defined by a binary LDPC-matrix corresponding to the LDPC-encoder encoding the encoded sequence, on the basis of the metrics.

### CROSS-REFERENCE TO RELATED APPLICATIONS

This application is based upon and claims the benefit of priority from prior Japanese Patent Application No. 2005-075933, filed Mar. 16, 2005, the entire contents of which are incorporated herein by reference.

### BACKGROUND OF THE INVENTION

1. Field of the Invention

This invention relates to an error-correcting-coding method and, more particularly, to an encoding method using an LDPC code.

2. Description of the Related Art

In a conventional LDPC (Low Density Parity Check) coding method, an information sequence composed of binary data is encoded by a generator matrix obtained from a check matrix of a binary LDPC code and a coded sequence composed of binary data is thereby obtained.

If the coded sequence of binary data thus obtained is applied to multilevel modulation such as 8-ary PSK (Phase Shift Keying), mapping of combining a plurality of binary bits in the coded sequence into one symbol of 8-aryPSK is required (see, for example, Japanese Patent Application No. 2003-176331).

On the receiving side (or reading side), metric information items corresponding to the plural bits need to be obtained from the received symbol when the mapped signal is decoded. At this time, likelihood information for each of the bits assigned to the received symbol is obtained by approximation. Thus, the likelihood information of each bit includes an error from the original value.

In the prior art, since the LDPC code is decoded with the metric value including such an error, this error gives a great influence to degradation in characteristics of iterative decoding of the LDPC code.

As the multilevel modulation, M-ary QAM (Quadrature Amplitude Modulation), M-ary PAM (Pulse Amplitude Modulation), OFDM (Orthogonal Frequency Division Multiplexing), CDMA (Code Division Multiple Access), etc. can be employed.

In addition, in the conventional LDPC code configuration for obtaining the multilevel coded sequence, a polynomial corresponding to a multileveled number to be used needs to be used to form a check matrix for obtaining a parity bit. In the configuration of the check matrix using the polynomial, the degree of freedom in the check matrix is reduced by using the polynomial and analysis required to retrieve the check matrix satisfying a codeword condition and, unlike the binary LDPC, an arbitrary coding rate or an arbitrary code length cannot be set freely.

### BRIEF SUMMARY OF THE INVENTION

An aspect of the present invention comprises a check bit generation unit configured to generate N-ary parity bits by processing information composed of N-ary symbols (where N is a power of 2) in modulo N with a low-density parity-check (LDPC) matrix composed of binary elements, an encoded sequence generation unit configured to generate an encoded sequence including the information composed of the N-ary symbols and the N-ary parity bits, a modulation unit configured to modulate the encoded sequence in a modulation scheme having N-ary modulation symbols to produce a modulated signal, a demodulation unit configured to demodulate the modulated signal to produce a demodulated signal, a metric generation unit configured to generate a metric for each of N modulation signal points from the demodulated signal to obtain a plurality of metrics, and a decoding unit configured to decode the encoded sequence by obtaining posteriori probabilities of the symbols in accordance with a state transition having an N state defined by a binary low-density parity-check (LDPC) matrix corresponding to the LDPC encoder encoding the encoded sequence, on the basis of the metrics.

Another aspect of the present invention comprises a check bit generation unit configured to generate N-ary parity bits by processing information composed of N-ary symbols (where N is a power of 2) in modulo N with a low-density parity-check (LDPC) matrix composed of binary elements, an encoded sequence generation unit configured to generate an encoded sequence including the information composed of the N-ary symbols and the N-ary parity bits; a recording unit configured to record the encoded sequence in a record medium, a reading unit configured to read an encoded sequence recorded in the record medium, a metric generation unit configured to generate a metric for each of N symbols from the encoded sequence, and a decoding unit configured to decode the encoded sequence by obtaining posteriori probabilities of the symbols in accordance with a state transition having an N state defined by the binary LDPC encoder encoding the encoded sequence, on the basis of the metrics.

### BRIEF DESCRIPTION OF THE SEVERAL VIEWS OF THE DRAWING

FIG. 1 is an illustration showing an operation of mapping a coded string of binary data on 8-ary PSK symbols;

FIG. 2 is an illustration showing a processing for obtaining a metric value on the basis of two nearest symbols;

FIG. 3 is an illustration showing an example of a check matrix employed for LDPC encoding;

FIG. 4 is an illustration showing a state transition in the decoding based on Sum-Product algorithm in a case where the state variable is two;

FIG. 5 is an illustration showing a state transition in the decoding based on Sum-Product algorithm in a case where the state variable is four;

FIG. 6 is an illustration showing signal point labels in application of QPSK modulation;

FIG. 7 is a block diagram showing a configuration of an encoder according to an embodiment of the present invention;

FIG. 8 is a block diagram showing a configuration of an N-ary LDPC encoder in the encoder shown in FIG. 7;

FIG. 9 is an illustration showing a bipartite graph corresponding to check matrix H shown in FIG. 3;

FIG. 10 is an illustration showing a processing for obtaining a metric value on the basis of two nearest symbol points;

FIG. 11 is an illustration showing a processing for obtaining a metric value on the basis of all the symbols;

FIG. 12 is a block diagram showing a configuration of a decoder suitable for the encoder shown in FIG. 7;

FIG. 13 is an illustration showing generator matrix G corresponding to the check matrix H shown in FIG. 3;

FIG. 14 is a block diagram showing a configuration of an N-ary LDPC encoder in a case of employing the generator matrix G shown in FIG. 13;

FIG. 15 is an illustration showing state transition in a case where state transition of the symbol using base 8 is represented with a state variable using base 4;

FIG. 16 is a block diagram showing a configuration of an encoder according to an embodiment of the present invention;

FIG. 17 is a block diagram showing a configuration of a decoder suitable for the encoder shown in FIG. 16;

FIG. 18 is a block diagram showing a configuration of an encoder according to an embodiment of the present invention;

FIG. 19 is a block diagram showing a configuration of a decoder suitable for the encoder shown in FIG. 18;

FIG. 20 is a block diagram showing a configuration of a modified example of the encoder shown in FIG. 18;

FIG. 21 is a block diagram showing a configuration of a decoder suitable for the encoder shown in FIG. 20;

FIG. 22 is a block diagram showing a configuration of an encoder according to an embodiment of the present invention;

FIG. 23 is a block diagram showing a configuration of a decoder suitable for the encoder shown in FIG. 22;

FIG. 24 is a block diagram showing a configuration of a modified example of the encoder shown in FIG. 22;

FIG. 25 is a block diagram showing a configuration of a decoder suitable for the encoder shown in FIG. 24;

FIG. 26 is a block diagram showing a configuration of a recording device according to an embodiment of the present invention;

FIG. 27 is a block diagram showing a configuration of a reading device suitable for the recording device shown in FIG. 26;

FIG. 28 is a block diagram showing a configuration of a recording device according to an embodiment of the present invention;

FIG. 29 is a block diagram showing a configuration of a reading device suitable for the recording device shown in FIG. 28;

FIG. 30 is a block diagram showing a configuration of a recording device according to an embodiment of the present invention;

FIG. 31 is a block diagram showing a configuration of a reading device suitable for the recording device shown in FIG. 30;

FIG. 32 is a block diagram showing a configuration of a recording device according to an embodiment of the present invention;

FIG. 33 is a block diagram showing a configuration of a reading device suitable for the recording device shown in FIG. 32;

FIG. 34 is a block diagram showing a configuration of a recording device according to an embodiment of the present invention;

FIG. 35 is a block diagram showing a configuration of a reading device suitable for the recording device shown in FIG. 34;

FIG. 36 is a block diagram showing a configuration of a recording device according to an embodiment of the present invention; and

FIG. 37 is a block diagram showing a configuration of a reading device suitable for the recording device shown in FIG. 36.

### DETAILED DESCRIPTION OF THE INVENTION

An embodiment of the present invention will be explained below.

According to the prior art, an LDPC code has been obtained by encoding an information sequence of binary data in check matrix H composed of binary elements with generator matrix G composed of binary elements that satisfies G×H=0 and corresponds to the check matrix. In this case, the encoded sequence is naturally obtained as binary data. If the encoded sequence composed of binary data is assigned to a signal point of multilevel modulation and then transmitted, a plurality of binary bits are converted into multilevel symbols and the multilevel symbols are transmitted as transmission symbols. FIG. 1 shows a mapping operation using, for example, 8-ary PSK.

If three bits are mapped to one symbol and then transmitted in this manner, reception metric of each binary bit included in one symbol needs to approximately obtain a metric value corresponding to each bit from the received 8-ary symbols, on the receiving side. As for this method, for example, a difference between distances from the received signal point to signal points nearest thereto to which binary bits 0 and 1 are assigned is generally handled as a metric value of each binary bit.

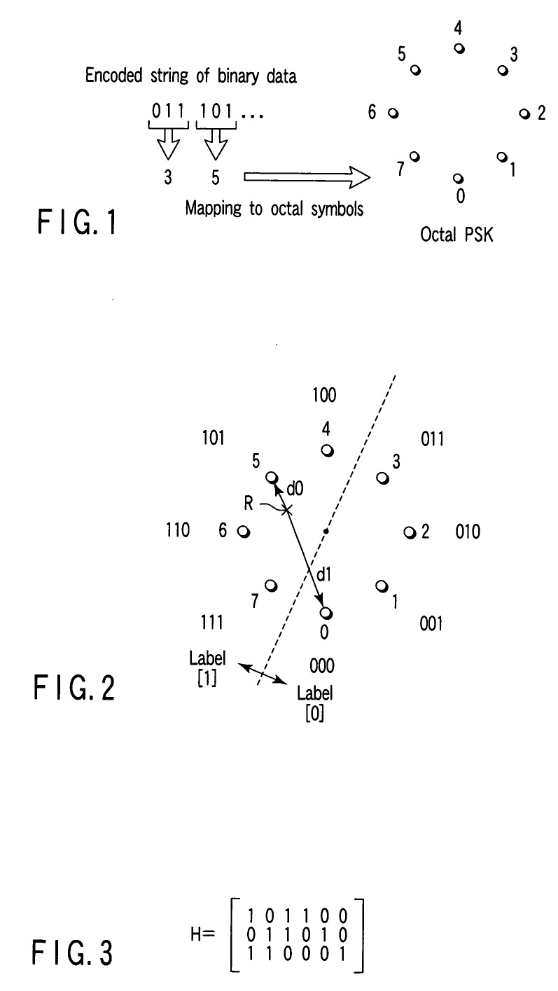

The metric value of each bit is obtained from a difference d0−d1 between distances d0 and d1 from the reception point to the nearest points of labels 0, 1 of each bit. FIG. 2 shows a case where the bits are assigned to 8-ary PSK. In this case, the nearest points of labels 0, 1 of the leading bit, to reception point R, are “0” and “5”. The metric value to the leading bit, of three bits assigned to the 8-ary PSK is obtained from difference d0−d1 between the distances d0 and d1.

In this manner, however, the obtained metric information is an approximate value since information about signals points other than the nearest points is not used. To obtain the optimum reception metric, the metric information about all of the signal points other than the nearest points needs to be used.

To use the metric information about all of the signal points of multilevel modulation, the transmitted encoded sequences assigned to the signal points need not to be binary, but to be represented with symbols of the used multileveled numbers. In addition, the assigned encoded sequences need to be applied to a decoder without decomposed as the metric of the symbol.

As a method of generating an encoded symbol for multilevel modulation with multileveled data, for example, TCM (Trellis Coded Modulation) using a convolutional code is employed. In the TCM, when the information sequence of binary data is encoded, the sequence including the parity bit is output with the multilevel symbol and transmitted by a transmit signal of the multilevel symbol, and decoding is executed with the metric in form of the multilevel symbol on the receiving side.

Thus, the present inventor proposes a method of LDPC code for obtaining an encoded sequence with N-ary symbol by using an LDPC check metric composed of binary elements for the input information converted as N-ary symbol and executing an operation (mod N). The mod N represents a remainder obtained by diving a certain value by N.

A general LDPC encoded bit sequence composed of binary data is formed by adding parity bits corresponding to the respective rows of the check matrix to the information sequence. For example, when check matrix H shown in FIG. 3 is used, parity to satisfy the following equation (1) is added:

$$\begin{matrix}a + c + d = 0 \\ b + c + e = 0 \\ a + b + f = 0\end{matrix} \} \qquad [ Equation 1 ]$$

The check matrix shown in FIG. 3 is the same as a matrix for obtaining parity bits d, e, f that satisfy the equation (1). In the equation (1), a, b, c correspond to an information bit string [a, b, c] and “+” represents exclusive OR. If the information sequence is [1, 0, 1], d=0, e=1, f=1 are obtained from the following equation (2).

$$\begin{matrix}1 + 1 + d = 0 \\ 0 + 1 + e = 0 \\ 1 + 0 + f = 0\end{matrix} \} \qquad [ Equation 2 ]$$

This operation corresponds to columns including 1 in each row of the check matrix. Three equations correspond to the rows of the check matrix H. This operation also corresponds to an operation of mod 2 using a sum of elements in the information sequence which are considered as 1 in the rows of the check matrix H. In the LDPC code, the parity bits obtained by this operation can be regarded as the state of the sequence.

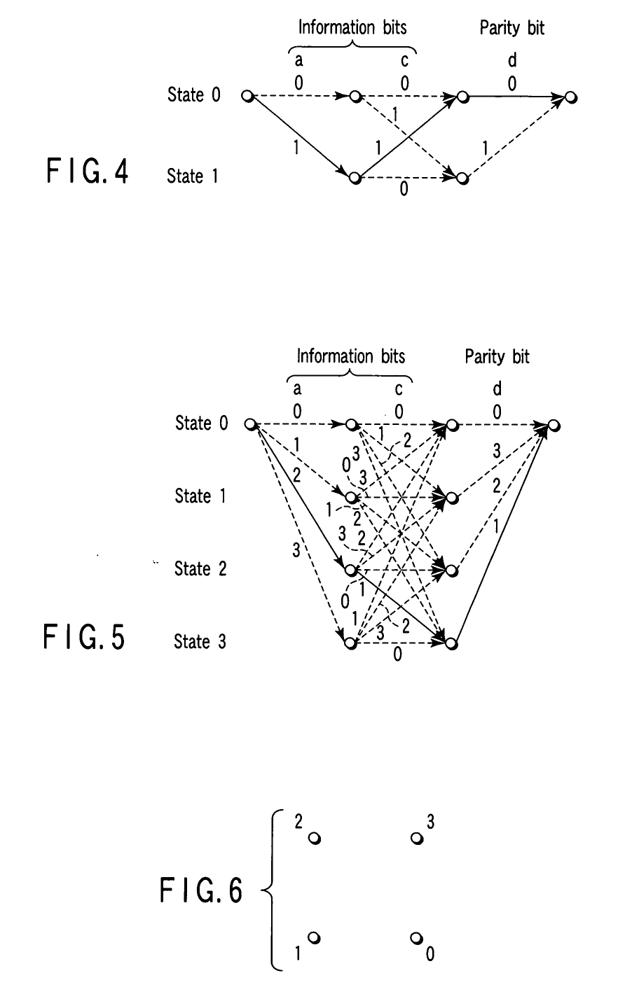

For example, if the work in the first row of the above equation is represented by state transition, the operation of mod 2 using a sum of information bits a, c corresponds to each state. In this example, the operation to obtain the parity bits can be defined as the state transition shown in, for example, FIG. 4. Under the condition that the state transition is defined, decoding can be executed by Sum-Product algorithm that is a general decoding method of LDPC.

In the state transition shown in FIG. 4, the states of information bits a, c transit as represented by solid lines. A bit corresponding to a branch connected with state 0 is assigned to the bit corresponding to parity bit d after the state transition of the information bits a, c. It can be easily understood from FIG. 4 that the bit assigned to d after the state transition of the information bits a, c is 0.

The encoded bit string becomes [a, b, c | d, e, f] after this work. In the above-explained example, the encoded bit string becomes [1, 0, 1 | 0, 1, 1]. It should be noted that the entire work is carried out by the operation of mod 2. The input information bits are 3 bits while the encoded bits are 6 bits. In general, this work is a basic matrix based on mod 2.

However, if it is considered that the work merely makes the element 1 of the check matrix H correspond to an address indicating which bit of the information sequence is noticed to generate the parity, the encoding work can be further extended in the following manner.

For example, a method of adding the parity based on mod 4 by using the check matrix H will be explained. The input information bit sequence is set to be a 6-bit sequence [1, 0, 1, 1, 0, 1]. If this bit sequence is further converted by 2 bits and regarded as an information sequence base on mod 4, the bit string becomes information [2, 3, 1]. If this sequence is applied to the equation as explained above, it can be expressed by the following equation (3).

$$\begin{matrix}2 + 1 + d = 0 \\ 3 + 1 + e = 0 \\ 2 + 3 + f = 0\end{matrix} \} \qquad [ Equation 3 ]$$

Thus, parity symbols [d, e, f] that satisfy the equation can be obtained. Parities d, e, f are handled as symbols based on mod 4. If the operation of the equation (3) is carried out on the basis of mod 4, d=1, e=0, f=3 are obtained. In this case, the encoded bit string becomes [2, 3, 1 | 1, 0, 3].

This operation is expressed as state transition in FIG. 5. FIG. 5 shows the state transition in the first row of the equation (3). In the state transition represented by a solid line, parity symbol d is 1 while input information symbols [a, c] are [2, 1]. Similarly, the encoding operation based on mod N is equivalent to encoding in the state transition having the state variable of N where N is a power of 2.

As explained in the example, the information symbol is a symbol modulo 4 and so is the parity symbol, in the encoding executed on the basis of mod 4. If the encoded string obtained from such 4-ary symbols is assigned to, for example, QPSK as shown in FIG. 6 that has 4-ary symbols as modulation signals, labels of the encoded symbols and labels of the information symbols can correspond one by one to each other.

The operation explained above cannot be executed in a basic matrix operation of the check matrix and information matrix, but it can be understood that the element 1 of the check matrix H is regarded as the address corresponding to the information symbol for parity generation.

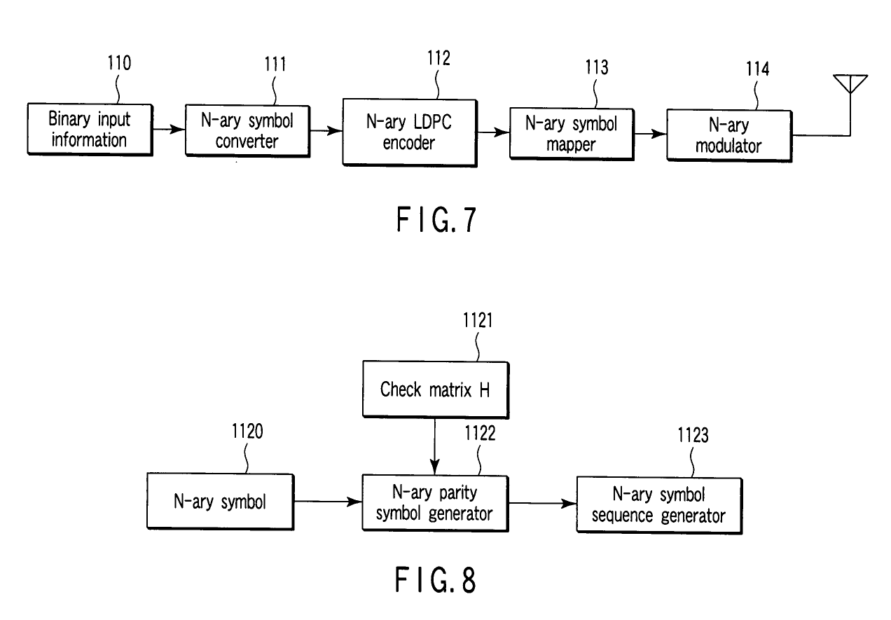

FIG. 7 shows a configuration of a first encoder which executes the above-described encoding. The first encoder comprises an N-ary symbol converter 111, an N-ary LDPC encoder 112, an N-ary symbol mapper 113, and an N-ary modulator 114. The encoding operation in a case where N=8 will be described below.

The N-ary symbol converter 111 converts binary input information 110 which is an input of an information bit (0, 1) sequence, for example, by three bits (for example, eight items: 000, 001, 010, 011, 100, 101, 110, 111), into 8-ary symbols (for example, 0, 1, 2, 3, 4, 5, 6, 7). In the case of N-ary symbol, the number of information bits to be converted is log₂N.

The N-ary LDPC encoder 112 processes the information converted into the 8-ary symbols by the N-ary symbol converter 111, by an operation modulo N, and generates the N-ary parity check bit. Thus, N-ary LDPC encoder 112 obtains and outputs a codeword (N-ary symbol information and the N-ary parity check bit) composed of the 8-ary symbols (for example, 0, 1, 2, 3, 4, 5, 6, 7).

The N-ary symbol mapper 113 assigns the encoded symbols of the codeword composed of the 8-ary symbols as output from the N-ary LDPC encoder 112 to signal points of modulation scheme having 8-ary signal points such as 8-PSK, respectively.

On the basis of an assignment result of the N-ary symbol mapper 113, the N-ary modulator 114 generates a signal modulated in 8-PSK, upconverts the modulated signal into a radio frequency signal, and transmits the radio frequency signal.

FIG. 8 shows a configuration of the N-ary LDPC encoder 112. The N-ary LDPC encoder 112 comprises a check matrix H which defines a general binary LDPC check matrix (1121), an N-ary parity symbol generator 1122, and an N-ary symbol sequence generator 1123.

The N-ary parity symbol generator 1122 generates a parity symbol sequence from the N-ary symbol 1120 that is output from the N-ary symbol converter 111 by directly using the check matrix H and outputs the generated parity symbol sequence and the N-ary symbol 1120.

The N-ary symbol sequence generator 1123 generates a codeword sequence composed of 8-ary symbols by synthesizing the N-ary symbol 1120 and the parity symbol sequence both output from the N-ary parity symbol generator 1122 and outputs the codeword sequence to the N-ary symbol mapper 113.

Next, an example of decoding the multilevel sequence will be described.

Since the check matrix H for the encoded symbol generated by the multilevel symbol is a binary LDPC check matrix, a bipartite graph defined by a general LDPC check matrix is applied to the check matrix H.

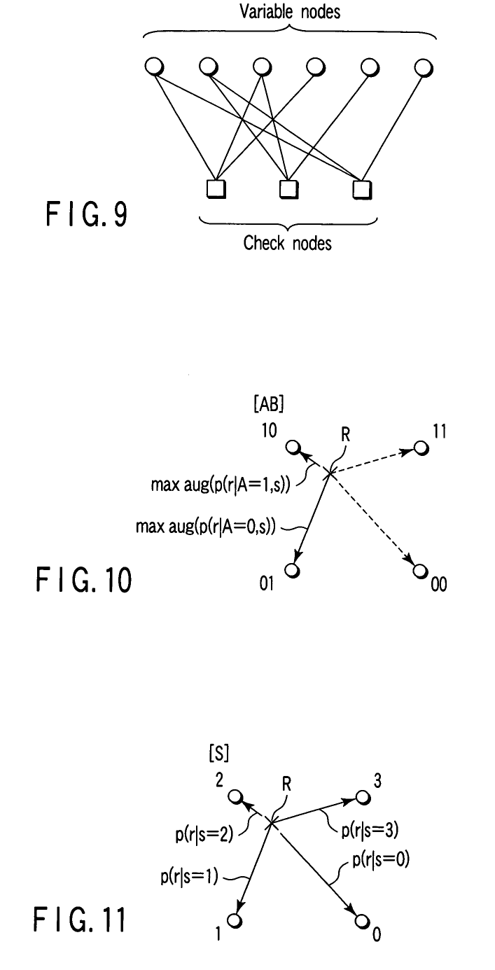

In other words, the multilevel encoded symbols can be decoded by the conventional Sum-Product algorithm as the encoded symbols remain multileveled. FIG. 9 shows a bipartite graph corresponding to the check matrix H shown in FIG. 3. Check nodes and their connections represent relationships in address between the information symbols of the equation (1) and the parity symbols generated from the equation (1).

The general LDPC code is subjected to decoding by the Sum-Product algorithm. After ending the Sum-Product algorithm, it is considered that correct reception has been carried out if a presumed encoded sequence [a, b, c, d, e, f] satisfies the check matrix H, i.e. equation (3). If the presumed encoded string does not satisfy the check matrix H or equation (3), it is considered that the received encoded sequence includes an error.

In the Sum-Product algorithm, decoding is carried out by processing the state transition defined by the check matrix H in maximum likelihood estimation by BCJR (Bahl Cocke Jelinek Raviv) algorithm.

The BCJR algorithm is a decoding algorithm for acquiring a posteriori probability of a symbol in each section by applying a metric value based on the label of each branch defined in the drawing of state transition. An approximate value has been used as the metric value assigned to each branch of each section in a case where the conventional LDPC code is applied to the multilevel modulation.

For example, metric values for respective two bits [A, B] assigned to QPSK are obtained in the following equation where a received QPSK signal is represented by r and a transmitted QPSK signal is represented by s.
metric (A=0)=max aug(p(r|A=0,s))
metric (A=1)=max aug(p(r|A=1,s))
metric (B=0)=max aug(p(r|B=0,s))
metric (B=1)=max aug(p(r|B=1,s)) [Equation 4]

aug(p(r|A=0,s)) represents a probability density function with binary bit A=0 received when the received value r is obtained after the transmission symbol r is transmitted. max( ) represents the maximum value of the probability density function.

In the case of QPSK, there are two transmission signal points to which the binary bit A=0 is assigned. One of the transmission signal points that have greater probability of transmission is considered approximate. A similar operation is also executed for binary bit B.

This operation is shown in, for example, FIG. 10. Since the metric values are obtained by using the information of two of four points which may be transmitted, the metric values for the respective transmission bits include an approximate error.

In the case of transmitting the 4-ary symbols obtained by the proposed encoding method by employing the QPSK, the metric values of the respective symbols can be obtained by the following equation where the transmitted 4-ary encoded symbols are represented by S.
metric (S=0)=p(r|s=0)
metric (S=1)=p(r|s=1)
metric (S=2)=p(r|s=2)
metric (S=3)=p(r|s=3) [Equation 5]

Since the encoded symbols have one-by-one correspondence to the modulated signals transmitted as represented by the equation, metric values obtained from the received signal point R are directly applied as the metric values of the respective encoded symbols. The metric values do not include an approximate error as seen in the case of assigning the binary bits. FIG. 11 shows the operation of the proposed encoding method.

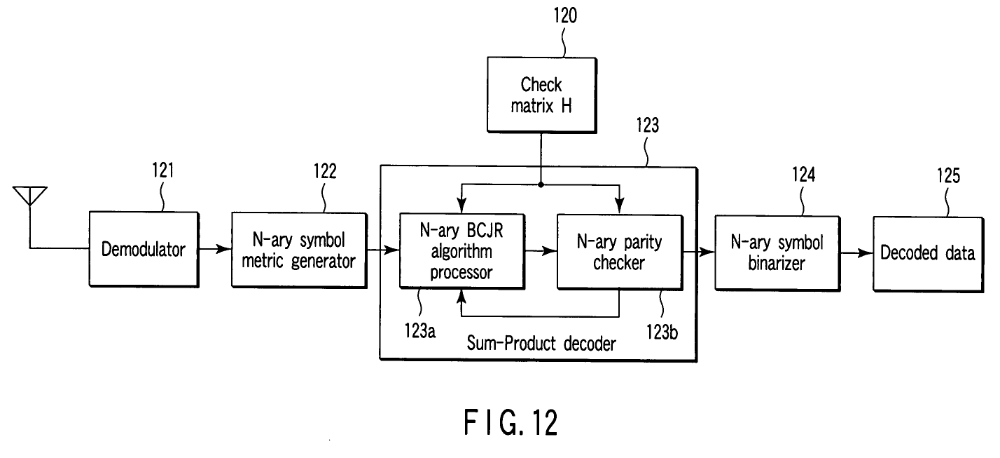

The metric values thus obtained are applied to the state transition for the multilevel symbols shown in FIG. 5, and the LDPC decoding is executed with the BCJR algorithm. FIG. 12 shows a configuration of a first decoder for executing such a decoding operation. The decoder corresponds to the N-ary LDPC encoder 112 shown in FIG. 7. The decoding operation in a case where N=8 will be explained below.

The first decoder shown in FIG. 12 stores a check matrix H 120, and comprises a demodulator 121, an N-ary symbol metric generator 122, a Sum-Product decoder 123 and an N-ary symbol binarizer 124.

The demodulator 121 receives, downconverts and demodulates a radio signal transmitted from the N-ary modulator 114.

The N-ary symbol metric generator 122 obtains the metric corresponding to each of the N-ary, i.e. 8-ary modulation signal points of the reception point R, from the receive signal demodulated by the demodulator 121. The metric is, for example, a distance between the receive signal and each of 8-ary signal points to be used for transmission.

The Sum-Product decoder 123 executes a decoding operation employing the above-described Sum-Product algorithm, on the basis of the metric obtained by the N-ary symbol metric generator 122. The Sum-Product decoder 123 is composed of an N-ary BCJR algorithm processor 123a and an N-ary parity checker 123b.

The N-ary BCJR algorithm processor 123a obtains the posteriori probability of each of the symbols in the N-ary code sequence by using the BCJR algorithm in accordance with the state transition shown in FIG. 5.

The N-ary parity checker 123b checks whether or not the decoding result composed of the N-ary symbols obtained by subjecting the posteriori probabilities obtained by the processor 123a to hard decision, satisfies the parity condition of the equation (3), i.e. whether or not the syndrome is 0. If the syndrome is 0, the decoding process is ended. If the syndrome is not 0, the processor 123a obtains the posteriori probabilities again and repeats the operation.

The information of a decoding result of the Sum-Product decoder 123 is decoded as the N-ary symbols. Thus, the N-ary symbol binarizer 124 restores the N-ary symbols to binary information (0, 1) (000, 001, 010, 011, 100, 101, 110, 111) similarly to the binary input information 110 and outputs the information as decoded data 125.

Thus, in the encoding method using the check matrix H, the encoded sequence is generated by obtaining the parity symbols directly from the check matrix H. Instead of this, encoding can be carried out by the generator matrix G which is generated from the check matrix H. The encoding operation using the generator matrix G will be described below.

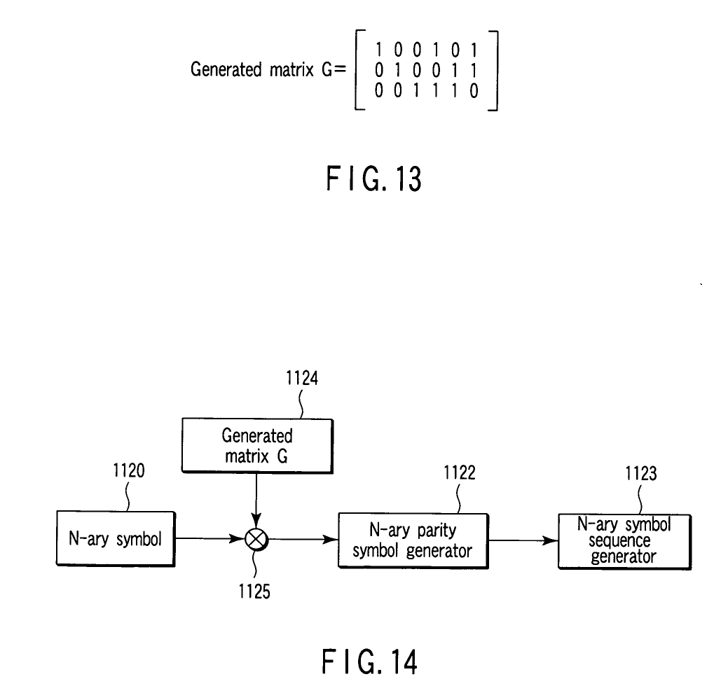

FIG. 13 shows the generator matrix G corresponding to the check matrix H shown in FIG. 3. The general binary LDPC code executes a matrix operation of [a, b, c]×G for binary information sequence [a, b, c] on the basis of mod 2 to obtain a 6-bit encoded bit string [a, b, c, d, e, f].

If the proposed multilevel symbol encoding method using the generator matrix G is executed with an operation based on mod 4 similarly to the above-explained example, necessary parity symbols are obtained from the encoding method by further processing the value of the matrix operation in the following manner, similarly to the binary elements.

When the input information is [2, 3, 1], the value [2, 3, 1]×G is a column vector of [2, 3, 1 | 3, 4, 5]. Right three symbols for the parity symbols do not satisfy the matrix equation based on the check matrix H. To correspond to the parity symbols satisfying the matrix equation, the symbols need to be obtained in the following equation.

Substituting the symbol values of the parity parts obtained on the basis of X of 4−(X mod 4) into the equation yields [1, 0, 3]. As the codeword, an encoded sequence similar to the codeword string obtained by the check matrix is obtained as [2, 3, 1 | 1, 0, 3].

In general, the multilevel operation based on mod N yields encoded symbol sequence Q from the matrix operation N−(X mod N) based on the operation modulo N using information symbol sequence C that satisfies mod N and the binary generator matrix G, as C×G=Q. The encoding method is not particularly limited if it satisfies the conditions of the check matrix H.

The generator matrix G obtained from the check matrix H, in any general form of check matrix, is in form of [I|P] where I represents unit matrix and P represents a transpose of the parity generator matrix. Thus, a codeword in form of [C|X] where C represents information symbol sequence and X represents parity symbol, is generated as the encoded sequence. C remains as it is while X is subjected to the above processing to become the parity symbol by the check matrix H.

FIG. 14 shows a configuration of the N-ary LDPC encoder 112 for generating the parity in this manner. The N-ary LDPC encoder 112 stores the generator matrix G that is generated from the check matrix H (1124) and comprises the N-ary parity symbol generator 1122, the N-ary symbol string generator 1123 and a multiplier 1125.

The multiplier 1125 executes a matrix operation based on mod N with the input N-ary symbols and the generator matrix G.

The N-ary parity symbol generator 1122 generates a parity symbol matrix from an output based on mod N of the multiplier 1125 based on mod N by using the generator matrix G and outputs the parity symbol matrix and the N-ary symbol 1120.

The N-ary symbol string generator 1123 generates a codeword string composed of 8-ary symbols by synthesizing the N-ary symbol 1120 and the parity symbol string both output from the N-ary parity symbol generator 1122 and outputs the codeword string to the N-ary symbol mapper 113.

In the above-explained configuration, since the N-ary encoded symbols are assigned to the N-ary modulation, the approximate error is not included in the metric value at the assignment of the binary symbols to the N-ary modulation and optimum reception can be thereby carried out.

Furthermore, an encoding method using extended multilevel symbols will be described.

In the above-described method of generating the codeword, the encoded symbol string based on mod N is obtained by inputting the information symbol sequence based on mod N to the binary check matrix H. The number of states of the state transition that should be considered is N. Thus, an encoding method using a further extended base of the information symbol will be described.

The input information bit sequence is [1, 0, 1, 1, 1, 0, 0, 1, 1], and information symbol sequence [5, 6, 3] modulo 8 is encoded by combining the input information sequence by three bits. The check matrix H shown in FIG. 3 is employed for the encoding, similarly to the above-described generating method. The parity symbols for the information symbol sequence composed of three symbols are regarded as [d, e, f] satisfying the following equation (6).

$$\begin{matrix}5 + 3 + d = 0 \\ 6 + 3 + e = 0 \\ 5 + 6 + f = 0\end{matrix} \} \qquad [ Equation 6 ]$$

The parity symbols are obtained by an operation of mod 8. The state transition is executed by setting the number of states at 8 in the above-described encoding method while the state transition having the number of states of 4 is considered in the current encoding method. In the equation (4), parity symbols [d, e, f] modulo 8 is obtained as [0, 7, 5]. The obtained encoded symbols are [5, 6, 3 | 0, 7, 5].

The state transition having the state number of 4 modulo 4 for an input symbol string modulo 8 will be considered. If the state transition is considered by substituting the symbol sequence modulo 8 for the state transition modulo 4, the symbols modulo 8 correspond to the symbols modulo 4, respectively, in the following manners.
symbols of mod 8→0, 1, 2, 3, 4, 5, 6, 7
states of mod 4→0, 1, 2, 3, 0, 1, 2, 3 [Equation 7]

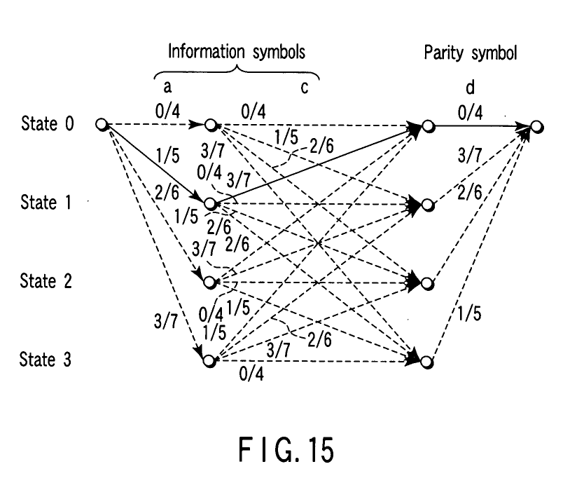

As understood from the correspondence, when the state transition of the symbols of mod 8 corresponds to the symbols of mod 4, two symbols are assigned to one state transition. FIG. 15 shows this state transition. The state transition in the first line of equation (4) is represented by a solid line in FIG. 15. If the state transition of the symbols modulo 8 is represented by the state number modulo 4, two inputs follow one common state transition as shown in FIG. 15.

The 8-ary symbols thus encoded are transmitted by, for example, 8-PSK having 8-ary signal points. In this case, the encoded symbols modulo 8 can be applied directly to each of the points of 8-PSK.

In addition, since the symbols may follow the same state transition by two different inputs, the receiving side needs to consider that the metric value assigned to the transition of a certain state is transmitted to two different points.

For example, in a case where the symbols are transmitted by 8-PSK, if the encoded symbol of 0 is transmitted, the encoded symbol follows the same state transition as symbol 4 in FIG. 15, by BCJR algorithm used for LDPC decoding on the receiving side. The basic operation of the BCJR algorithm is not changed even if different symbols follow the same state transition.

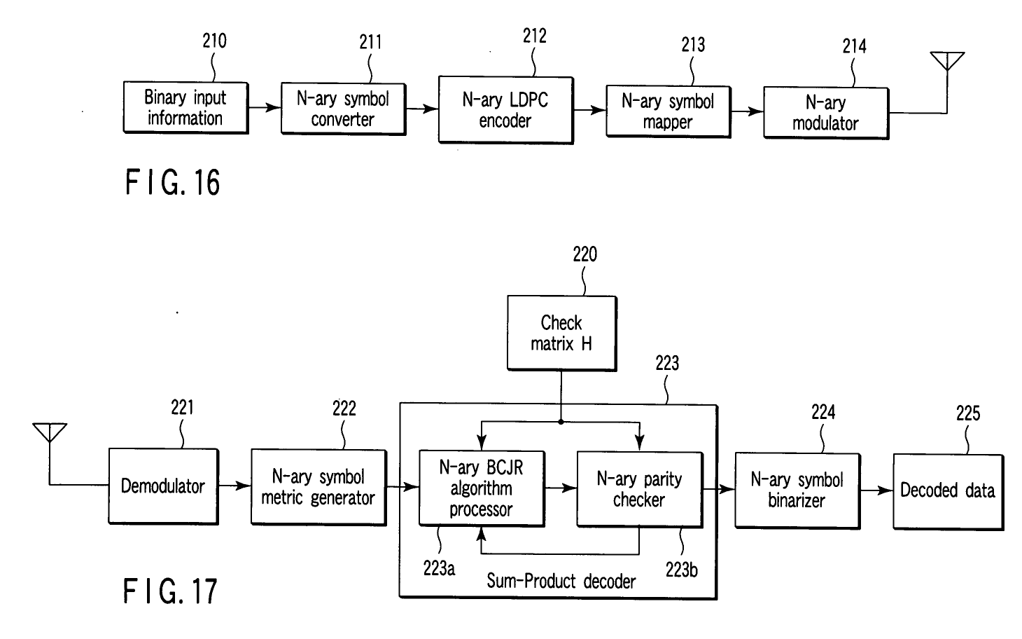

FIG. 16 shows a configuration of a second encoder that executes the above-described operation. The second encoder comprises an N-ary symbol converter 211, an N-ary LDPC encoder 212, an N-ary symbol mapper 213, and an N-ary modulator 214. The encoding operation in a case where N=8 will be described below.

The N-ary symbol converter 211 converts binary input information 210 which is an input of an information bit (0, 1) sequence, for example, by three bits (for example, eight items: 000, 001, 010, 011, 100, 101, 110, 111), into 8-ary symbols (for example, 0, 1, 2, 3, 4, 5, 6, 7). In the case of N-ary symbol, the number of information bits to be converted is log₂N.

The N-ary LDPC encoder 212 comprises a configuration as shown in FIG. 8 or FIG. 14, similarly to the N-ary LDPC encoder 112. The N-ary LDPC encoder 212 converts the information converted into the 8-ary symbols by the N-ary symbol converter 211, into the LDPC code, and generates the N-ary parity check bit of the LDPC encoded information by an operation modulo M.

Thus, N-ary LDPC encoder 212 obtains and outputs a codeword (N-ary information and the N-ary parity check bit) composed of the 8-ary symbols (for example, 0, 1, 2, 3, 4, 5, 6, 7). The information is 8-ary symbols (for example, 0, 1, 2, 3, 4, 5, 6, 7). The parity symbols accompanying the information is naturally generated with 4-ary symbols (for example, 0, 1, 2, 3).

The N-ary symbol mapper 213 assigns the encoded symbols of the codeword composed of the 4-ary symbols as output from the N-ary LDPC encoder 212 to signal points of modulation scheme having 8-ary signal points such as 8-PSK, respectively. The 4-ary parity symbols are also assigned by use of any four points of the 8-ary signal points.

On the basis of an assignment result of the N-ary symbol mapper 213, the N-ary modulator 214 generates a signal modulated in 8-PSK, upconverts the modulated signal into a radio frequency signal, and transmits the radio frequency signal.

FIG. 17 shows a configuration of a second decoder for decoding the encoded signal. The second decoder corresponds to the second encoder shown in FIG. 16. The decoding operation in a case where N=8 will be explained below.

The second decoder shown in the drawing stores a check matrix H 220, and comprises a demodulator 221, an N-ary symbol metric generator 222, a Sum-Product decoder 223 and an N-ary symbol binarizer 224.

The demodulator 221 receives, downconverts and demodulates a radio signal transmitted from the N-ary modulator 214.

The N-ary symbol metric generator 222 obtains the metric corresponding to each of the N-ary, i.e. 8-ary modulation signal points of the reception point R, from the receive signal demodulated by the demodulator 221. The metric is, for example, a distance between the receive signal and each of 8-ary signal points to be used for transmission.

The Sum-Product decoder 223 executes a decoding operation with the above-explained Sum-Product algorithm, on the basis of the metric obtained by the N-ary symbol metric generator 222. The Sum-Product decoder 223 is composed of an N-ary BCJR algorithm processor 223a and an N-ary parity checker 223b.

The N-ary BCJR algorithm processor 223a obtains the posteriori probability of each of the symbols in the N-ary code string by using the BCJR algorithm in accordance with the state transition shown in FIG. 15. The state number is in M state corresponding to the M-ary symbols of the parity symbols.

The N-ary parity checker 223b checks whether or not the decoding result composed of the N-ary symbols obtained by subjecting the posteriori probabilities obtained by the processor 223a to hard decision, satisfies the parity condition, i.e. whether or not the syndrome is 0. If the syndrome is 0, the decoding process is ended. If the syndrome is not 0, the processor 223a obtains the posteriori probabilities again and repeats the operation.

The information of a decoding result of the Sum-Product decoder 223 is decoded as the N-ary symbols. Thus, the N-ary symbol binarizer 224 restores the N-ary symbols to binary information (0, 1) (000, 001, 010, 011, 100, 101, 110, 111) similarly to the binary input information 210 and outputs the information as decoded data 225.

In the above-described configuration, too, N-ary encoded symbols are assigned to the N-ary modulation. Thus, the metric value does not include an approximate error at the assignment of the binary symbols to the N-ary modulation, and the optimum reception can be carried out.

Since the state transition having the N-ary state corresponds to the M-ary symbols, the state number can be decreased or increased, the minimum free distance of the encoder can be extended, the performance can be improved and the operation amount can be reduced.

An encoding method of binarizing again the information encoded with the multilevel symbol will be further considered. In the general binary LDPC encoding system, the sequence length of the code to be used is defined due to the size of the check matrix H.

For example, in a case of using a check matrix of 5,000 rows and 10,000 columns, the codeword bit length has the code length of 10,000 bits, and an encoded sequence having the information bit length of 5,000 bits, parity bit length of 5,000 bits and coding rate of a half is generated.

If the information is encoded in this method and output as the multilevel symbols, an encoded sequence having code length of 10,000 in which each of the symbols are multilevel is generated. For example, if the binary information bit sequence is converted by three bits and then the encoding method based on mod 8 is executed, the encoded symbol length generated by the check matrix is 10,000. If the encoded symbol length is further binarized, a codeword having the encoded bit length of 30,000 bits is generated. In this case, an encoded sequence having the input bit length of 15,000 bits and parity bit length of 15,000 bits is generated.

When the encoded bit sequence thus binarized twice is used, the metric value of the symbol corresponding to mod 8 needs to be generated again from the received signal and decoded again by the BCJR algorithm, on the receiving side.

The LDPC code has a very forceful ability of error correction if it has a long code length. In the proposed case, for example, even if a check matrix from which an encoded sequence of approximately 1,000 bits is used, the code length can be increased to 1,000×log₂N by encoding a plurality of bits, in the encoding method having a basis of mod N.

In this case, even if the same check matrix is used, encoding gain having a code length of 1,000×log₂N can be acquired by the LDPC as compared with encoding using binary data of 1,000 bits.

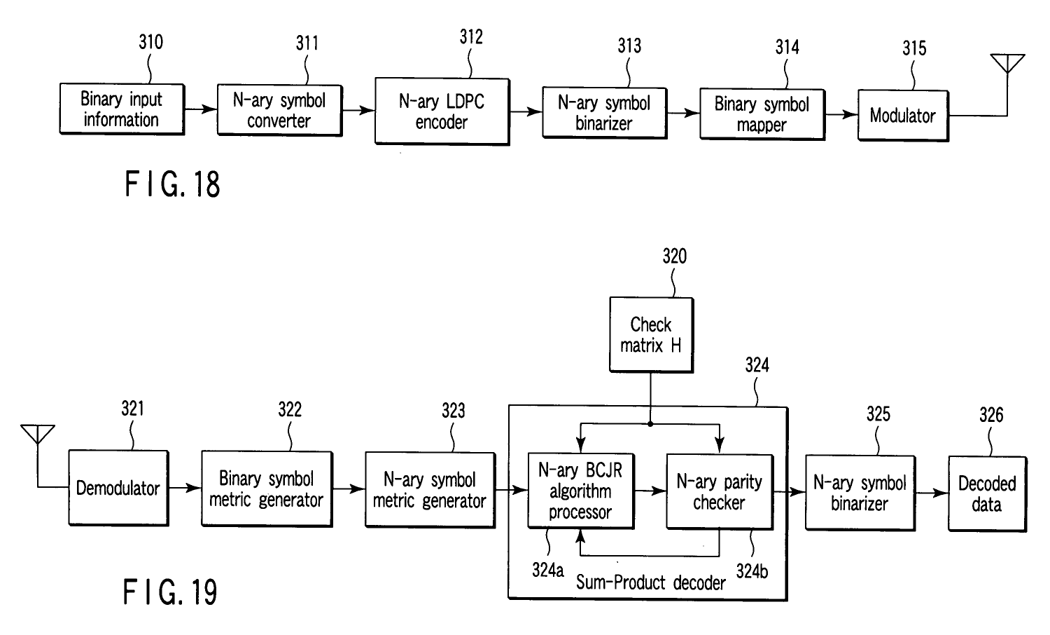

FIG. 18 shows a configuration of a third encoder that executes the above-described operation. The third encoder comprises an N-ary symbol converter 311, an N-ary LDPC encoder 312, an N-ary symbol binarizer 313, a binary symbol mapper 314, and a modulator 315. The encoding operation in a case where N=8 will be described below.

The N-ary symbol converter 311 converts binary input information 310 which is an input of an information bit (0, 1) sequence, for example, by three bits (for example, eight items: 000, 001, 010, 011, 100, 101, 110, 111), into 8-ary symbols (for example, 0, 1, 2, 3, 4, 5, 6, 7). In the case of N-ary symbol, the number of information bits to be converted is log₂N.

The N-ary LDPC encoder 312 comprises a configuration as shown in FIG. 8 or FIG. 14, similarly to the N-ary LDPC encoder 112. The N-ary LDPC encoder 312 converts the information converted into the 8-ary symbols by the N-ary symbol converter 311, into the LDPC code, and generates the N-ary parity check bit of the LDPC encoded information by an operation modulo N. Thus, N-ary LDPC encoder 312 obtains and outputs a codeword (N-ary information and the N-ary parity check bit) composed of the 8-ary symbols (for example, 0, 1, 2, 3, 4, 5, 6, 7).

The N-ary symbol binarizer 313 converts again each of the symbols in the codeword obtained by the N-ary LDPC encoder 312 into binary symbols (0, 1) (for example, eight items: 000, 001, 010, 011, 100, 101, 110, 111).

The binary symbol mapper 314 assigns the encoded symbols of the codeword composed of the binary symbols as output from the N-ary symbol binarizer 313 to signal points of modulation scheme having M-ary signal points such as M-ary PSK, respectively.

On the basis of an assignment result of the binary symbol mapper 314, the modulator 315 generates a signal modulated in M-ary PSK, upconverts the modulated signal into a radio frequency signal, and transmits the radio frequency signal.

FIG. 19 shows a configuration of a third decoder for decoding the encoded signal. The decoder corresponds to the third encoder shown in FIG. 18. The decoding operation in a case where N=8 will be explained below.

The third decoder shown in FIG. 19 stores a check matrix H 320, and comprises a demodulator 321, a binary symbol metric generator 322, an N-ary symbol metric generator 323, a Sum-Product decoder 324 and an N-ary symbol binarizer 325.

The demodulator 321 receives, downconverts and demodulates a radio signal transmitted from the modulator 315.

The binary symbol metric generator 322 generates a metric value of the bit corresponding to each of the transmitted binary codeword symbols, from the receive signal demodulated by the demodulator 321.

The N-ary symbol metric generator 323 obtains the metric corresponding to N-ary (for example, 8-ary) symbols by synthesizing the metric values generated by the binary symbol metric generator 322. For example, each metric value is added to “110” to obtain the metric of symbol “6”.

The Sum-Product decoder 324 executes a decoding operation with the above-explained Sum-Product algorithm, on the basis of the metric obtained by the N-ary symbol metric generator 323. The Sum-Product decoder 324 is composed of an N-ary BCJR algorithm processor 324a and an N-ary parity checker 324b.

The N-ary BCJR algorithm processor 324a obtains the posteriori probability of each of the symbols in the N-ary code sequence by using the BCJR algorithm in accordance with the state transition of the parity symbol generation of the encoder shown in FIG. 18.

The N-ary parity checker 324b checks whether or not the decoding result composed of the N-ary symbols obtained by subjecting the posteriori probabilities obtained by the processor 324a to hard decision, satisfies the parity condition, i.e. whether or not the syndrome is 0. If the syndrome is 0, the decoding process is ended. If the syndrome is not 0, the processor 324a obtains the posteriori probabilities again and repeats the operation.

The information of a decoding result of the Sum-Product decoder 324 is decoded as the N-ary symbols. Thus, the N-ary symbol binarizer 325 restores the N-ary symbols to binary information (0, 1) (000, 001, 010, 011, 100, 101, 110, 111) similarly to the binary input information 210 and outputs the information as decoded data 326.

In this case, an approximate error is caused at the metric generation on the receiving side, by assignment of the binary information to the multilevel symbols. However, robustness to an error of a burst symbol in the communication channel such as fading can be obtained by decomposing the encoded symbol sequence composed of N-ary symbols into a plurality of binary symbols by an interleaver as explained below and transmitting the binary symbols such that correlation between the binary symbols is reduced.

Since the sequence encoded by the N-ary symbols is decomposed into the binary symbols, the encoded sequence having a log₂N-time code length and the encoded gain of the LDPC can be improved.

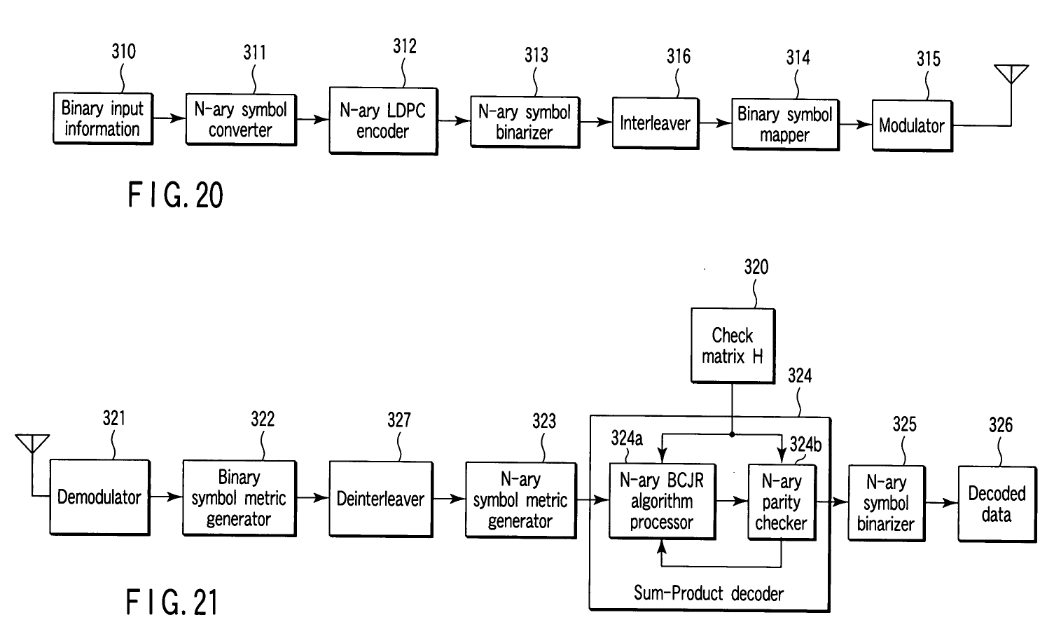

The third encoder shown in FIG. 18 can be modified as shown in FIG. 20. In other words, an interleaver 316 is provided between the N-ary symbol binarizer 313 and the binary symbol mapper 314 in the third encoder shown in FIG. 18.

The interleaver 316 interleaves a permutation of the encoded symbols of the codeword composed of the binary symbols which are output from the N-ary symbol binarizer 313, to change the order of the encoded symbols.

The binary symbol mapper 314 assigns the encoded symbols interleaved by the interleaver 316 to the signal points of modulation scheme having M-ary signal points of the M-ary PSK, respectively.

In response to the third encoder, the third decoder shown in FIG. 19 is modified as shown in FIG. 21. In other words, a deinterleaver 327 is provided between the binary symbol metric generator 322 and the N-ary symbol metric generator 323 in the third decoder shown in FIG. 19.

The deinterleaver 327, which corresponds to the interleaver 316, returns the order of the metric values generated by the binary symbol metric generator 322 to the original order that is the same as the order in the codeword changed by the interleaver 316.

The N-ary symbol metric generator 323 obtains the metric values corresponding to N-ary (for example, 8-ary) symbols by synthesizing the metric values output from the interleaver 327.

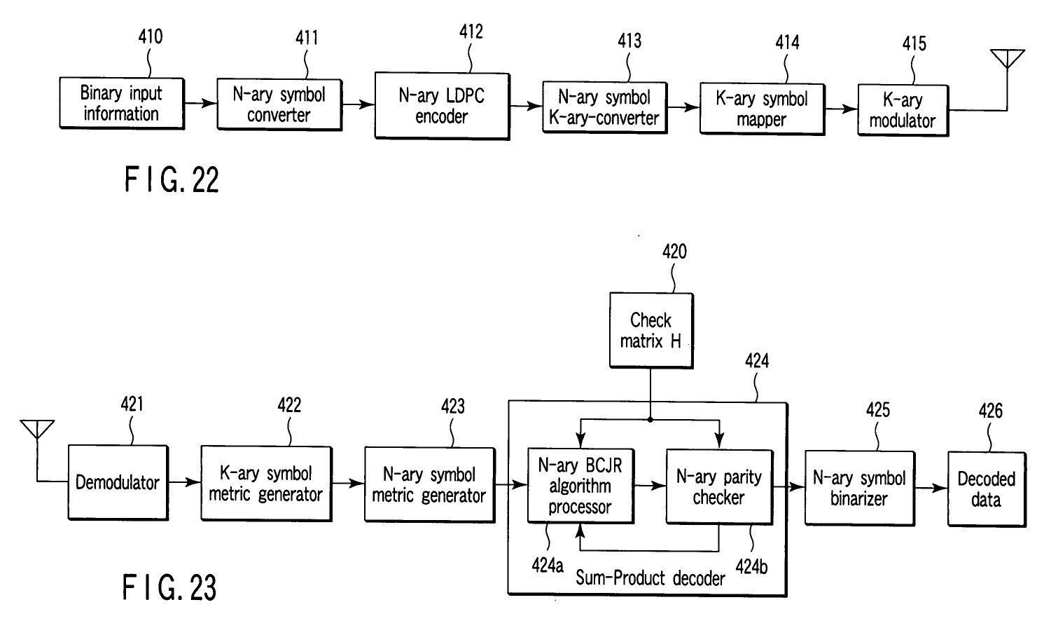

Otherwise, a method of further converting a plurality of symbols into multilevel symbols, a method of decomposing one multilevel symbol into a plurality of low-order bits, etc. can be employed. One of them is shown in FIG. 22 as a fourth encoder.

The fourth encoder comprises an N-ary symbol converter 411, an N-ary LDPC encoder 412, an N-ary symbol K-ary-converter 413, a K-ary symbol mapper 414, and a K-ary Modulator 415. The encoding operation in a case where N=8 will be described below.

The N-ary symbol converter 411 converts binary input information 410 which is an input of an information bit (0, 1) sequence, for example, by three bits (for example, eight items: 000, 001, 010, 011, 100, 101, 110, 111), into 8-ary symbols (for example, 0, 1, 2, 3, 4, 5, 6, 7). In the case of N-ary symbol, the number of information bits to be converted is log₂N.

The N-ary LDPC encoder 412 comprises a configuration as shown in FIG. 8 or FIG. 14, similarly to the N-ary LDPC encoder 112. The N-ary LDPC encoder 412 converts the information converted into 8-ary symbols by the N-ary symbol converter 411, into the LDPC code, and generates the N-ary parity check bit of the LDPC encoded information by an operation modulo N. Thus, N-ary LDPC encoder 412 obtains and outputs a codeword (N-ary information and the N-ary parity check bit) composed of the 8-ary symbols (for example, 0, 1, 2, 3, 4, 5, 6, 7).

The N-ary symbol K-ary-converter 413 converts each of the symbols in the codeword obtained by the N-ary LDPC encoder 412 into K-ary symbol (for example, hexadecimal symbol: 0, 1, 2, 3, 4, 5, 6, 7, 8, 9, 10, 11, 12, 13, 14, 15).

The K-ary symbol mapper 414 assigns the encoded symbols in the codeword composed of the K-ary symbols output from the N-ary symbol K-ary-converter 413 to the signal points of the modulation scheme having K-ary signal points of K-ary PSK, etc., respectively.

On the basis of an assignment result of the K-ary symbol mapper 414, the K-ary Modulator 415 generates a signal modulated in K-ary PSK, upconverts the modulated signal into a radio frequency signal, and transmits the radio frequency signal.

FIG. 23 shows a configuration of a fourth decoder for decoding the encoded signal. The decoder corresponds to the fourth encoder shown in FIG. 22. The decoding operation in a case where N=8 will be explained below.

The fourth decoder shown in FIG. 23 stores a check matrix H 420, and comprises a demodulator 421, a K-ary symbol metric generator 422, an N-ary symbol metric generator 423, a Sum-Product decoder 424, and an N-ary symbol binarizer 425.

The demodulator 421 receives, downconverts and demodulates a radio signal transmitted from the modulator 315.

The K-ary symbol metric generator 422 generates a metric value of the bit corresponding to each of the transmitted K-ary codeword symbols, from the receive signal demodulated by the demodulator 221.

The N-ary symbol metric generator 423 obtains the metric corresponding to N-ary (for example, 8-ary) symbols by synthesizing the metric values generated by the K-ary symbol metric generator 422. For example, each metric value is added to “124” to obtain the metric of symbol “7”.

The Sum-Product decoder 424 executes a decoding operation with the above-explained Sum-Product algorithm, on the basis of the metric obtained by the N-ary symbol metric generator 423.

The Sum-Product decoder 424 is composed of an N-ary BCJR algorithm processor 424a and an N-ary parity checker 424b.

The N-ary BCJR algorithm processor 424a obtains the posteriori probability of each of the symbols in the N-ary code string by using the BCJR algorithm in accordance with the state transition of the parity symbol generation of the encoder shown in FIG. 22.

The N-ary parity checker 424b checks whether or not the decoding result composed of the N-ary symbols obtained by subjecting the posteriori probabilities obtained by the processor 424a to hard decision, satisfies the parity condition, i.e. whether or not the syndrome is 0. If the syndrome is 0, the decoding process is ended. If the syndrome is not 0, the processor 424a obtains the posteriori probabilities again and repeats the operation.

The information of a decoding result of the Sum-Product decoder 424 is decoded as the N-ary symbols. Thus, the N-ary symbol binarizer 425 restores the N-ary symbols to binary information (0, 1) (000, 001, 010, 011, 100, 101, 110, 111) similarly to the binary input information 210 and outputs the information as decoded data 426.

In the above-described configuration, the N-ary symbols are decomposed into or synthesized to the K-ary symbols. Therefore, high-speed communications can be implemented by dispersing the influence from the extension of the code length and the communication channel in the decomposition and shortening the transmit symbol length in the synthesis.

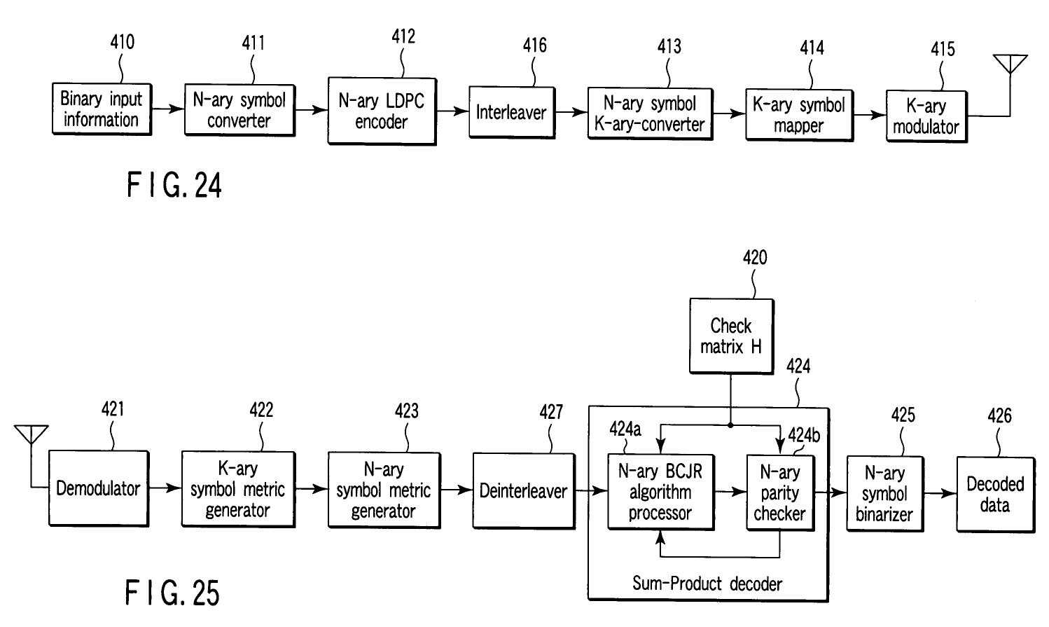

The fourth encoder shown in FIG. 22 can be modified as shown in FIG. 24. In other words, an interleaver 416 is provided between the N-ary symbol encoder 412 and the N-ary symbol K-ary-converter 413 in the fourth encoder shown in FIG. 22.

The interleaver 416 interleaves a permutation of the encoded symbols of the codeword composed of the 8-ary symbols which are output from the N-ary LDPC encoder 412, to change the order of the encoded symbols.

The N-ary symbol K-ary-converter 413 converts the encoded symbols interleaved by the interleaver 416 into K-ary symbols (for example, hexadecimal symbols: 0, 1, 2, 3, 4, 5, 6, 7, 8, 9, 10, 11, 12, 13, 14, 15).

In response to the fourth encoder, the fourth decoder shown in FIG. 23 is modified as shown in FIG. 25. In other words, a deinterleaver 427 is provided between the N-ary symbol metric generator 423 and the Sum-Product decoder 424 in the fourth decoder shown in FIG. 23.

The deinterleaver 427, which corresponds to the interleaver 416, returns the order of the metrics generated by the N-ary symbol metric generator 423 to the original order that is the same as the order in the codeword changed by the interleaver 416.

The Sum-Product decoder 424 executes a decoding operation with the above-explained Sum-Product algorithm, on the basis of the metrics output from the deinterleaver 427.

The present invention is not limited to the embodiments described above but the constituent elements of the invention can be modified in various manners without departing from the spirit and scope of the invention. Various aspects of the invention can also be extracted from any appropriate combination of a plurality of constituent elements disclosed in the embodiments. Some constituent elements may be deleted in all of the constituent elements disclosed in the embodiments. The constituent elements described in different embodiments may be combined arbitrarily.

In the above-described embodiment, for example, the encoder and the decoder transmit the information via radio communications. However, the transmission means is not limited to the radio communications, but can be applied to cable communications.

In addition, the present invention is applied to the communications, but can also be applied to writing the information to a storage medium or reading the information therefrom.

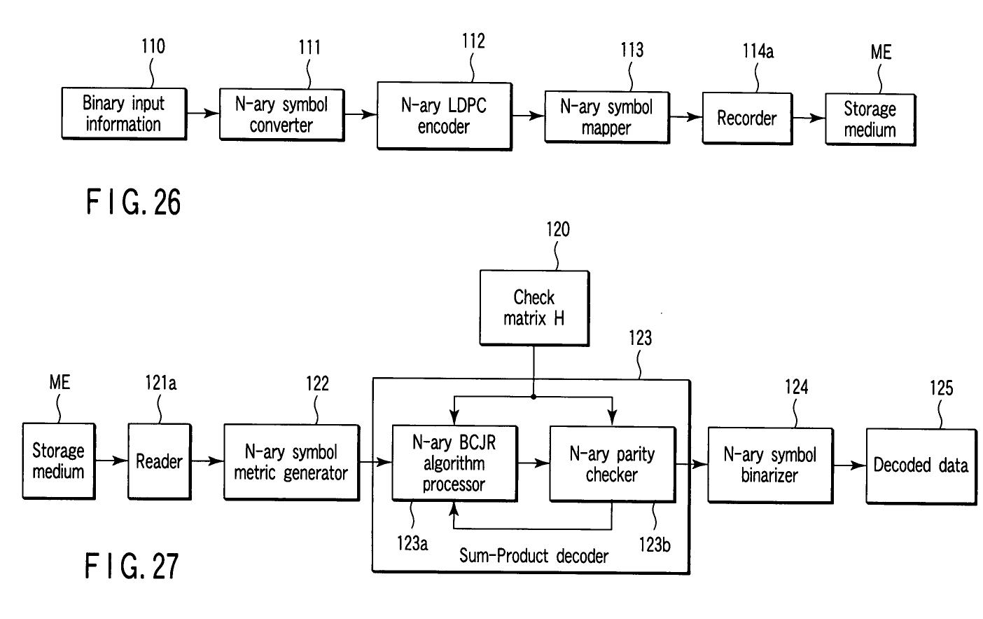

For example, FIG. 26 shows a configuration of a recording device for recording the information in a storage medium such as a semiconductor memory, an optical medium, a hard disk, etc. In the configuration, the N-ary modulator 114 shown in FIG. 7 is replaced with a recorder 114a.

The recorder 114a executes a well-known recording control corresponding to the storage medium, and records the information based on the assignment result of the N-ary symbol mapper 113 in the storage medium under the mapping rule having the N-ary symbols. The storage medium may be built in the recording device or detachable therefrom.

FIG. 27 shows an example of a reading device suitable for the recording device. The reading device reads the information stored in the storage medium. In FIG. 27, the demodulator 121 of the decoder shown in FIG. 12 is replaced with a reader 121a.

The reader 121a executes a well-known reading control corresponding to the storage medium, and reads the information from the storage medium and outputs the information to the N-ary symbol metric generator 122 under the mapping rule having the N-ary symbols. The reader may be integrated with the recording device shown in FIG. 26, may exist as an independent unit. The storage medium may be detachable from the reader.

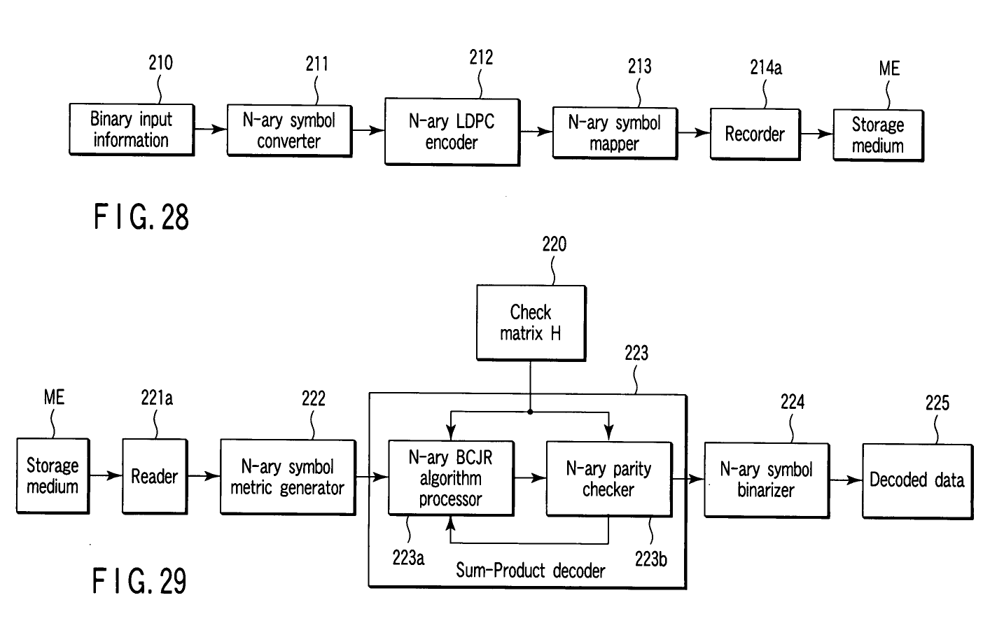

In addition, for example, the recording device may have a configuration shown in FIG. 28. The recording device records the information in a storage medium such as a semiconductor memory, an optical medium, a hard disk, etc. In the configuration, the N-ary modulator 214 shown in FIG. 16 is replaced with a recorder 214a.

The recorder 214a executes a well-known recording control corresponding to the storage medium, and records the information based on the assignment result of the N-ary symbol mapper 213 in the storage medium under the mapping rule having the N-ary symbols. The storage medium may be built in the recording device or detachable therefrom.

FIG. 29 shows an example of a reading device suitable for the recording device. The reading device reads the information stored in the storage medium. In FIG. 29, the demodulator 221 of the decoder shown in FIG. 17 is replaced with a reader 221a.

The reader 221a executes a well-known reading control corresponding to the storage medium, and reads the information from the storage medium and outputs the information to the N-ary symbol metric generator 222 under the mapping rule having the N-ary symbols. The reader may be integrated with the recording device shown in FIG. 28, may exist as an independent unit. The storage medium may be detachable from the reader.

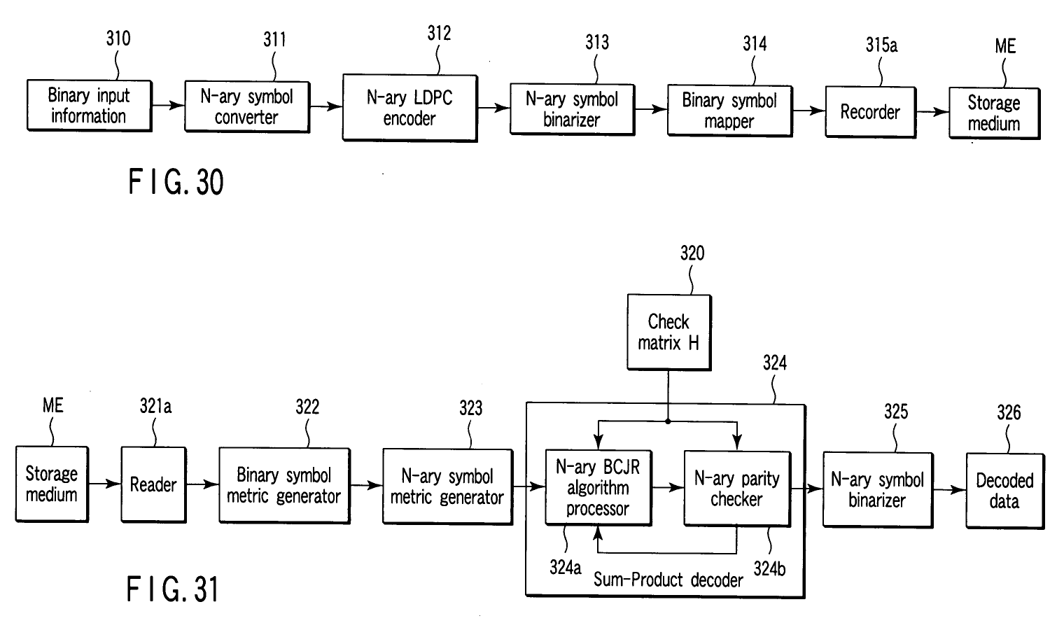

Moreover, for example, the recording device may have a configuration shown in FIG. 30. The recording device records the information in a storage medium such as a semiconductor memory, an optical medium, a hard disk, etc. In the configuration, the modulator 315 of the encoder shown in FIG. 18 is replaced with a recorder 315a.

The recorder 315a executes a well-known recording control corresponding to the storage medium, and records the information based on the assignment result of the binary symbol mapper 314 in the storage medium under the mapping rule having the binary symbols. The storage medium may be built in the recording device or detachable therefrom.

FIG. 31 shows an example of a reading device suitable for the recording device. The reading device reads the information stored in the storage medium. In FIG. 31, the demodulator 321 of the decoder shown in FIG. 19 is replaced with a reader 321a.

The reader 321a executes a well-known reading control corresponding to the storage medium, and reads the information from the storage medium and outputs the information to the binary symbol metric generator 322 under the mapping rule having the binary symbols. The reader may be integrated with the recording device shown in FIG. 30, may exist as an independent unit. The storage medium may be detachable from the reader.

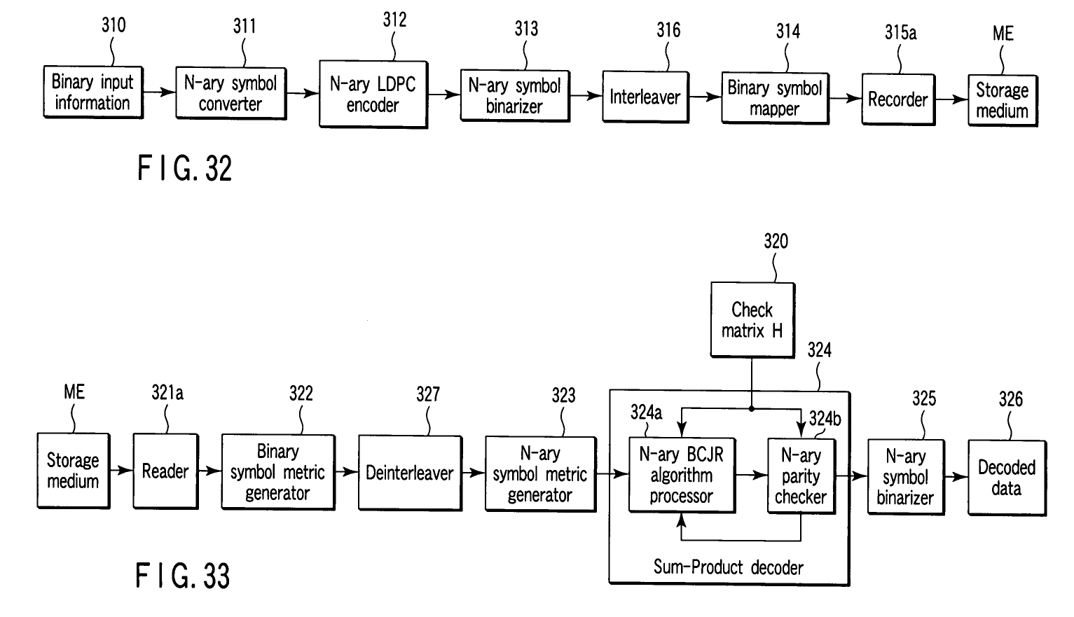

Furthermore, for example, the recording device may have a configuration shown in FIG. 32. The recording device records the information in a storage medium such as a semiconductor memory, an optical medium, a hard disk, etc. In the configuration, the modulator 315 of the encoder shown in FIG. 20 is replaced with a recorder 315a.

The recorder 315a executes a well-known recording control corresponding to the storage medium, and records the information based on the assignment result of the binary symbol mapper 314 in the storage medium under the mapping rule having the binary symbols. The storage medium may be built in the recording device or detachable therefrom.

FIG. 33 shows an-example of a reading device suitable for the recording device. The reading device reads the information stored in the storage medium. In FIG. 33, the demodulator 321 of the decoder shown in FIG. 21 is replaced with a reader 321a.

The reader 321a executes a well-known reading control corresponding to the storage medium, and reads the information from the storage medium and outputs the information to the binary symbol metric generator 322 under the mapping rule having the binary symbols. The reader may be integrated with the recording device shown in FIG. 32, may exist as an independent unit. The storage medium may be detachable from the reader.

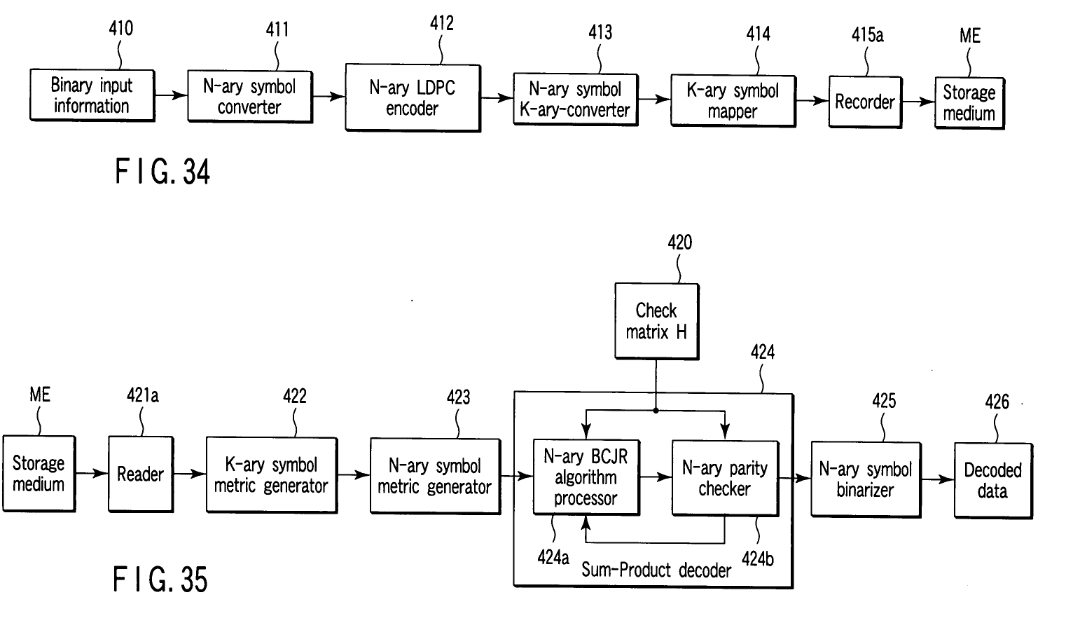

Furthermore, for example, the recording device may have a configuration shown in FIG. 34. The recording device records the information in a storage medium such as a semiconductor memory, an optical medium, a hard disk, etc. In the configuration, the K-ary modulator 415 of the encoder shown in FIG. 22 is replaced with a recorder 415a.

The recorder 415a executes a well-known recording control corresponding to the storage medium, and records the information based on the assignment result of the K-ary symbol mapper 414 in the storage medium under the mapping rule having the K-ary symbols. The storage medium may be built in the recording device or detachable therefrom.

FIG. 35 shows an example of a reading device suitable for the recording device. The reading device reads the information stored in the storage medium. In FIG. 35, the demodulator 421 of the decoder shown in FIG. 23 is replaced with a reader 421a.

The reader 421a executes a well-known reading control corresponding to the storage medium, and reads the information from the storage medium and outputs the information to the K-ary symbol metric generator 422 under the mapping rule having the K-ary symbols. The reader may be integrated with the recording device shown in FIG. 34, may exist as an independent unit. The storage medium may be detachable from the reader.

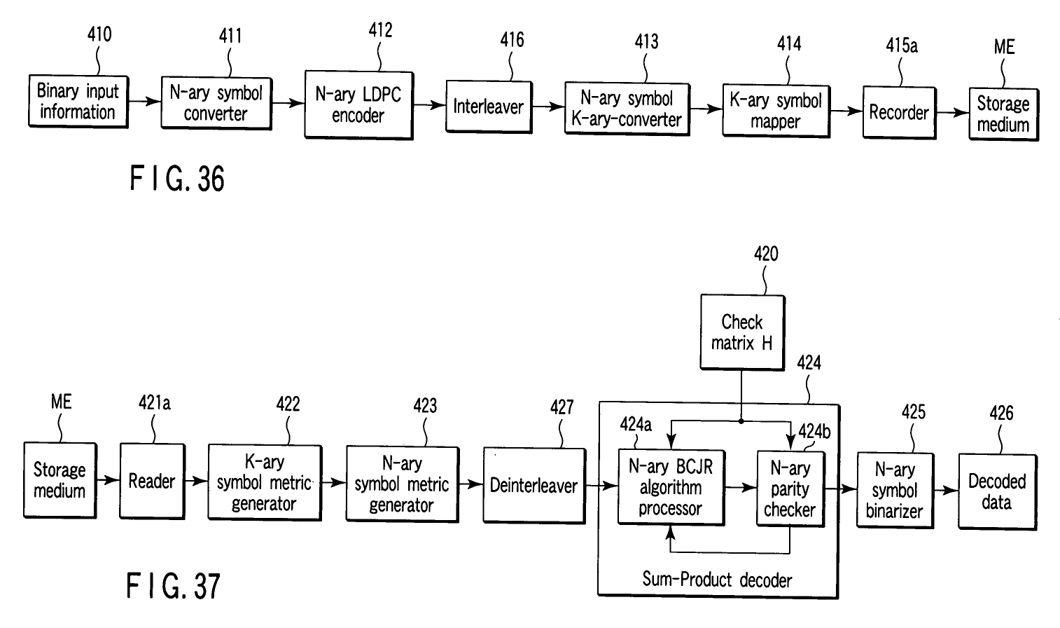

Furthermore, for example, the recording device may have a configuration shown in FIG. 36. The recording device records the information in a storage medium such as a semiconductor memory, an optical medium, a hard disk, etc. In the configuration, the K-ary modulator 415 of the encoder shown in FIG. 24 is replaced with a recorder 415a.

The recorder 415a executes a well-known recording control corresponding to the storage medium, and records the information based on the assignment result of the K-ary symbol mapper 414 in the storage medium under the mapping rule having the K-ary symbols. The storage medium may be built in the recording device or detachable therefrom.

FIG. 37 shows an example of a reading device suitable for the recording device. The reading device reads the information stored in the storage medium. In FIG. 37, the demodulator 421 of the decoder shown in FIG. 25 is replaced with a reader 421a.

The reader 421a executes a well-known reading control corresponding to the storage medium, and reads the information from the storage medium and outputs the information to the K-ary symbol metric generator 422 under the mapping rule having the K-ary symbols. The reader may be integrated with the recording device shown in FIG. 36, may exist as an independent unit. The storage medium may be detachable from the reader.

Needless to say, the present invention can also be variously modified within a scope which does not depart from the gist of the present invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An encoding method comprising:
generating N-ary parity bits by processing information composed of N-ary symbols (where N is a power of 2) in modulo N with a low-density parity-check (LDPC) matrix composed of binary elements;
generating an encoded sequence including the information composed of the N-ary symbols and the N-ary parity bits; and
modulating the encoded sequence in a modulation scheme having N-ary modulation symbols.

2. An encoding method comprising:
generating M-ary parity bits by processing information composed of N-ary symbols in modulo M (where M is a power of 2 smaller than N) with a low-density parity-check (LDPC) matrix composed of binary elements;
generating an encoded sequence including the information composed of the N-ary symbols and the M-ary parity bits; and
modulating the encoded sequence in a modulation scheme having N-ary modulation symbols.

3. An encoding method comprising:
generating N-ary parity bits by processing information composed of N-ary symbols (where N is a power of 2) in modulo N with a low-density parity-check (LDPC) matrix composed of binary elements;
generating an encoded sequence including the information composed of the N-ary symbols and the N-ary parity bits;
converting the encoded sequence into K-ary symbols (where K is a power of 2 and is not binary); and
modulating the K-ary symbols, in a modulation scheme having K-ary modulation symbols.

4. An encoding method comprising:
generating N-ary parity bits by processing information composed of N-ary symbols (where N is a power of 2) in a state transition having an N state with a low-density parity-check (LDPC) matrix composed of binary elements;
generating an encoded sequence including the information composed of the N-ary symbols and the N-ary parity bits;
converting the encoded sequence into binary symbols; and
modulating the binary symbols, in a modulation scheme having binary modulation symbols.

5. An encoding method comprising:
generating N-ary parity bits by processing information composed of N-ary symbols (where N is a power of 2) in a state transition having an N state with a low-density parity-check (LDPC) matrix composed of binary elements;
generating an encoded sequence including the information composed of the N-ary symbols and the N-ary parity bits;
converting the encoded sequence into binary symbols; and
modulating the binary symbols in a modulation scheme having K-ary symbols (where K is a power of 2 and is not binary).

6. The encoding method according to claim 1, wherein generating the N-ary parity bits includes generating N-ary parity bit X by a matrix operation based on N−(X mod N), in the modulo N with a generator matrix generated from the LDPC matrix.

7. A decoding method comprising:
demodulating a signal modulated in a modulation scheme having K-ary modulation symbols (where K is a natural number greater than 2);
generating a metric for each of K modulation signal points from the demodulated signal to obtain a plurality of metrics; and
decoding the modulated signal by obtaining posteriori probabilities of the symbols in accordance with a state transition having an N state defined by a binary low-dencity parity-check (LDPC) matrix corresponding to the LDPC encoder encoding an encoded sequence (where N is a power of 2), on the basis of the metrics.

8. A decoding method comprising:
demodulating a signal modulated in a modulation scheme having K-ary modulation symbols (where K is a natural number greater than 2);
generating a metric for each of K modulation signal points from the demodulated signal to obtain a plurality of metrics; and
decoding the modulated signal by obtaining posteriori probabilities of the symbols in accordance with a state transition having an M state defined by a binary low-density parity-check (LDPC) matrix corresponding to the LDPC encoder encoding an encoded sequence (where M is a power of 2 smaller than N), on the basis of the metrics.

9. A decoding method comprising:
demodulating a signal modulated in a modulation scheme having K-ary modulation symbols (where K is a natural number greater than 2);
generating a metric for each of K modulation signal points from the demodulated signal to obtain a plurality of first metrics;
converting the first metrics into second metrics corresponding to N-ary metrics (where N is a power of 2); and
decoding the modulated signal by obtaining posteriori probabilities of the symbols in accordance with a state transition having an N state defined by a binary low-density parity-check (LDPC) matrix corresponding to the LDPC encoder encoding an encoded sequence, on the basis of the second metrics.

10. The decoding method according to claim 7, further comprising processing a decoded sequence obtained by the decoding in modulo N and discriminating whether or not a parity condition of an check matrix composed of binary elements is met, on the basis of a result of the modulo N, and obtaining a syndrome of a parity symbol of the decoded sequence by using the binary LDPC matrix.

11. An encoding system comprising:
a check bit generation unit configured to generate N-ary parity bits by processing information composed of N-ary symbols (where N is a power of 2) in modulo N with a low-density parity-check (LDPC) matrix composed of binary elements;
an encoded sequence generation unit configured to generate an encoded sequence including the information composed of the N-ary symbols and the N-ary parity bits;
a modulation unit configured to modulate the encoded sequence in a modulation scheme having N-ary modulation symbols to produce a modulated signal;
a demodulation unit configured to demodulate the modulated signal to produce a demodulated signal;
a metric generation unit configured to generate a metric for each of N modulation signal points from the demodulated signal to obtain a plurality of metrics; and
a decoding unit configured to decode the encoded sequence by obtaining posteriori probabilities of the symbols in accordance with a state transition having an N state defined by a binary low-density parity-check (LDPC) matrix corresponding to the LDPC encoder encoding the encoded sequence, on the basis of the metrics.

12. A recording method comprising:
generating N-ary parity bits by processing information composed of N-ary symbols (where N is a power of 2) in modulo N with a low-density parity-check (LDPC) matrix composed of binary elements;
generating an encoded sequence including the information composed of the N-ary symbols and the N-ary parity bits; and
recording the encoded sequence in a record medium.

13. A reading method comprising:
reading information recorded by K-ary symbols (where K is a natural number greater than 2) from a record medium;
obtaining a metric for each of K symbols from the information to obtain a plurality of metrics; and
decoding the information by obtaining posteriori probabilities of the symbols in accordance with a state transition having an N state defined by a binary LDPC matrix corresponding to the LDPC encoder using in the recoder (where N is a power of 2), on the basis of the metrics.

14. A recording system comprising:
a check bit generation unit configured to generate N-ary parity bits by processing information composed of N-ary symbols (where N is a power of 2) in modulo N with a low-density parity-check (LDPC) matrix composed of binary elements;
an encoded sequence generation unit configured to generate an encoded sequence including the information composed of the N-ary symbols and the N-ary parity bits;
a recording unit configured to record the encoded sequence in a record medium;
a reading unit configured to read an encoded sequence recorded in the record medium;
a metric generation unit configured to generate a metric for each of N symbols from the encoded sequence; and
a decoding unit configured to decode the encoded sequence by obtaining posteriori probabilities of the symbols in accordance with a state transition having an N state defined by the binary LDPC encoder encoding the encoded sequence, on the basis of the metrics.

15. An encoding method comprising:
inputting N-ary symbols (where N is a power of 2);
outputting an encoded sequence including the information composed of the N-ary symbols and the N-ary parity bits, which is generated by processing information composed of N-ary symbols in modulo N with a low-density parity-check (LDPC) matrix composed of binary elements; and
modulating the encoded sequence including the information composed of the N-ary symbols and the N-ary parity bits, in a modulation scheme having N-ary modulation symbols.
